(19) United States
(12) Patent Application Publication
(10) Pub. No.: US 2026/0150629 A1
(43) Pub. Date: May 28, 2026

(54) SEMICONDUCTOR STRUCTURES WITH INTEGRATED LASER DEBONDING TEST STRUCTURES

(71) Applicant: International Business Machines Corporation, Armonk, NY (US)

(72) Inventors: Qianwen Chen, Fort Collins, CO (US); Joshua Mark Rubin, Albany, NY (US); Nicholas Alexander Polomoff, Hopewell Junction, NY (US); John Knickerbocker, Monroe, NY (US)

(21) Appl. No.: 18/956,379

(22) Filed: Nov. 22, 2024

(51) Int. Cl. H10P 74/00

(52) U.S. Cl. CPC H10P 74/273

(57) ABSTRACT

A semiconductor structure includes a back-end-of-line region including a first level of metal interconnects and a second level of metal interconnects separated by at least one interlayer dielectric layer, and a laser debonding test structure disposed in the back-end-of-line region. The laser debonding test structure includes a testable metal plate layer disposed within the at least one interlayer dielectric layer between the first level of metal interconnects and the second level of metal interconnects, a set of test pads, and a set of vias, at least a subset of the set of vias extending from at least one test pad in the set of test pads to the testable metal plate layer disposed within the at least one interlayer dielectric layer between the first level of metal interconnects and the second level of metal interconnects.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater number of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

A field-effect transistor (FET) is a three-terminal device having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Integrated circuits may be formed using front-end-of-line (FEOL) processing for fabricating devices, such as FETs, on a wafer, and back-end-of-line (BEOL) processing for interconnecting such devices on the wafer. Following FEOL and BEOL processing, a wafer may be separated or divided into multiple integrated circuit chips by dicing or other suitable techniques.

### SUMMARY

Embodiments of the invention provide techniques for forming semiconductor structures with integrated laser debonding test structures.

In one embodiment, a semiconductor structure includes a back-end-of-line region including a first level of metal interconnects and a second level of metal interconnects separated by at least one interlayer dielectric layer, and a laser debonding test structure disposed in the back-end-of-line region. The laser debonding test structure includes a testable metal plate layer disposed within the at least one interlayer dielectric layer between the first level of metal interconnects and the second level of metal interconnects, a set of test pads, and a set of vias, at least a subset of the set of vias extending from at least one test pad in the set of test pads to the testable metal plate layer disposed within the at least one interlayer dielectric layer between the first level of metal interconnects and the second level of metal interconnects.

In another embodiment, a semiconductor structure includes a first level of metal interconnects, at least one interlayer dielectric layer disposed over the first level of metal interconnects, a second level of metal interconnects disposed over the at least one interlayer dielectric layer, a metal-insulator-metal capacitor disposed within the at least one interlayer dielectric layer, the metal-insulator-metal capacitor including a first metal capacitor plate and a second metal capacitor plate separated by an insulating layer, a testable metal plate layer of a laser debonding test structure disposed within the at least one interlayer dielectric layer, the testable metal plate layer being spaced apart from and substantially coplanar with one of the first metal capacitor plate and the second metal capacitor plate, and one or more vias extending from the testable metal plate layer through the at least one interlayer dielectric layer to a metal interconnect in the second level of metal interconnects.

In another embodiment, an integrated circuit includes a semiconductor structure including a front-end-of-line region comprising one or more active device components, a back-end-of-line region disposed over the front-end-of-line region, the back-end-of-line region comprising a first level of metal interconnects and a second level of metal interconnects separated by at least one interlayer dielectric layer, and a laser debonding test structure disposed in the back-end-of-line region. The laser debonding test structure including a testable metal plate layer disposed within the at least one interlayer dielectric layer between the first level of metal interconnects and the second level of metal interconnects, a set of test pads, and a set of vias, at least a subset of vias in the set of vias extending from at least one test pad in the set of test pads to the testable metal plate layer disposed within the at least one interlayer dielectric layer between the first level of metal interconnects and the second level of metal interconnects.

### BRIEF DESCRIPTION OF THE DRAWINGS

FIG. 1 shows a cross-sectional view of a semiconductor structure with an integrated laser debonding test structure, according to an embodiment of the invention.

FIG. 2 shows a laser debonding process for separating a device wafer from a handle wafer, according to an embodiment of the invention.

FIG. 3 shows a top-down view of a device wafer having an integrated laser debonding test structure formed proximate an edge of the device wafer, according to an embodiment of the invention.

FIG. 4 shows a top-down view of a calibration wafer having an integrated laser debonding test structure, according to an embodiment of the invention.

FIGS. 5A-5E show cross-sectional views of a semiconductor structure illustrating a process for formation of an integrated laser debonding test structure therein, according to an embodiment of the invention.

FIGS. 6A-6D show cross-sectional views of a semiconductor structure illustrating another process for formation of an integrated laser debonding test structure therein, according to an embodiment of the invention.

FIGS. 7A-7E show cross-sectional views of a semiconductor structure illustrating another process for formation of an integrated laser debonding test structure therein, according to an embodiment of the invention.

FIG. 8 shows a cross-sectional view of a semiconductor structure with an integrated laser debonding test structure, according to an embodiment of the invention.

FIG. 9 shows an integrated circuit comprising one or more semiconductor structures with integrated laser debonding test structures, according to an embodiment of the invention.

### DETAILED DESCRIPTION

Illustrative embodiments of the invention may be described herein in the context of illustrative methods for forming semiconductor structures with integrated laser debonding test structures, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

An integrated circuit may be formed using front-end-of-line (FEOL) processing for fabricating devices (e.g., transistors, capacitors, resistors, etc.) on a wafer and back-end-of-line (BEOL) processing for interconnecting such devices on the wafer. More particularly, BEOL processes are typically focused on forming metal interconnects between the different devices of an integrated circuit, whereas the fabrication of the different devices that make up the integrated circuit is typically done during FEOL processing.

In FEOL processing, devices such as complementary metal-oxide-semiconductor (CMOS) field-effect transistors (FET) devices are formed by a series of steps. For example, masking layers (e.g., photolithographic masks) may be used to form patterns on a semiconductor substrate or wafer. Such masking layers may be used to control or define specific regions where material is to be etched or removed, as well as to control or define specific regions where material is to be formed (e.g., through deposition, growth, etc.). In some cases, materials may be blanket deposited, followed by patterning of one or more masking layers to remove previously deposited materials in some areas while leaving the previously deposited material in other areas. A FEOL region of a semiconductor structure is an example of what is more generally referred to as an active device region comprising one or more active devices (e.g., transistors and other logic devices).

In BEOL processing, fabrication of an integrated circuit continues by forming interconnects through one or more layers of wiring and dielectric passivation layers over active devices in a FEOL region formed during the FEOL processing. Interconnections or interconnects may include metallic structures that are formed in multiple levels of interlayer dielectric (ILD) layers for electrically connecting the various devices in the FEOL region. Following FEOL and BEOL processing, a wafer may be separated or divided into multiple integrated circuit chips by dicing or other suitable techniques.

The fabrication, handling and integration of semiconductor wafer structures may utilize various bonding and debonding processes. Advanced semiconductor and packaging integration processing may require nano-scale precision in controlled environments (e.g., absent contamination, with uniform temperature control and semiconductor process compatibility at temperatures ranging from room temperature to approximately 400 degrees Celsius (° C), etc.) with various wafer form factors (e.g., including 300 millimeter (mm) wafer form factors) for a variety of use cases, including prototyping, high volume manufacturing, etc. Heterogeneous integration may involve or utilize various different fabrication processes, including thin wafers and thin layer handling, processing and integration at the wafer scale. Handling wafers, also referred to as handle wafers or temporary handler platforms, may be formed of glass or silicon. Silicon handling wafers, also referred to as silicon handlers, provide various advantages, including compatibility with various manufacturing equipment, advantages in material properties including high thermal conductivity for rapid heating and cooling, having a coefficient of thermal expansion (CTE) that matches device wafers also formed of silicon, etc.

For high precision in the fabrication, handling and integration of semiconductor wafer structures, including nano-scale semiconductor wafer structures, infrared (IR) or other laser debonding approaches may be utilized. A silicon handler may be coated with a release layer (e.g., designed for IR or other laser debonding technology) and bonded to a device wafer (e.g., which may have active devices or components formed therein or thereon) via a bonding adhesive. The bonding adhesive may be a low or high temperature compatible adhesive. As discussed above, the use of the silicon handler provides a number of advantages including compatibility with semiconductor processes and equipment to allow for various processing to be performed on the device wafer. Such processing may include, for example, thinning and polishing of the backside of the device wafer, fabrication of backside interconnects and other structures on the backside of the device wafer, etc. Once such processing is completed, then the silicon handler is separated from the device wafer using a precision-controlled laser beam that is directed through the silicon handler to the release layer. The release layer is configured to have a high electromagnetic energy absorption targeted at IR wavelengths and other laser debonding process control parameters, which enables separation of the silicon handler from the bonding adhesive that connects it to the device wafer.

IR and other laser debonding processes, however, may impact the device wafer. For example, if the laser beam that is transmitted is too high power, this can impact components formed on or in the device wafer (e.g., causing device shifts, shorts, opens, etc.). Illustrative embodiments provide approaches for forming integrated laser debonding test structures in a device wafer to allow for determining impacts of IR or other laser debonding processes on the device wafer (e.g., components formed in or on the device wafer) following laser irradiation.

In some embodiments, a semiconductor structure includes a BEOL region having two or more metallization levels, with vias being formed between metal interconnects at different ones of the two or more metallization levels. The semiconductor structure includes one or more “mid-via” metal plate layers for a laser debonding test structure, where “mid-via” refers to the metal plate layers of the laser debonding test structure being positioned within interlevel dielectric (ILD) layers between different metallization levels of the BEOL region, where vias are formed between metal interconnects in such different metallization levels. The mid-via metal plate layers are formed of a high absorption metal such as tantalum (Ta), tantalum nitride (TaN), titanium (Ti), titanium nitride (TiN), etc. The mid-via metal plate layers of the laser debonding test structure may be formed at the same time as metal plate layers for one or more metal-insulator-metal (MIM) capacitors also formed in the BEOL region (e.g., mid-via MIM capacitors). The metal plate layers of the laser debonding test structure may each have a thickness of about 10 to 100 nanometers (nm). The BEOL region includes metal interconnects and vias, which may be fabricated using copper (Cu) damascene processing, aluminum (Al) BEOL fabrication processes, etc. The metal plate layers of the laser debonding test structure, also referred to as testable metal plate layers, are electrically connected with interconnects and vias in the BEOL region to form the laser debonding test structure.

The laser debonding test structures described herein provide various technical benefits, including providing high sensitivity for incoming laser beams (e.g., used as part of an IR or other laser debonding process) and providing an “on-chip” low-cost solution, since the laser debonding test structure may be fabricated with the same processing used for forming MIM capacitors in the BEOL region of the semiconductor structure. Further, the laser debonding test structure can include testable metal plate layers with different sensitivities to incoming laser beams, due to the different thicknesses of dielectric material on top of the different testable metal plate layers that are part of the laser debonding test structure. The different testable metal plate layers may also have different sensitivities due to their depth within the BEOL stack, since they may be positioned at one or more layers of the BEOL build. Further, the testable metal plate layers may have different thicknesses at different layers or levels of the BEOL stack and/or may contain different metal compositions.

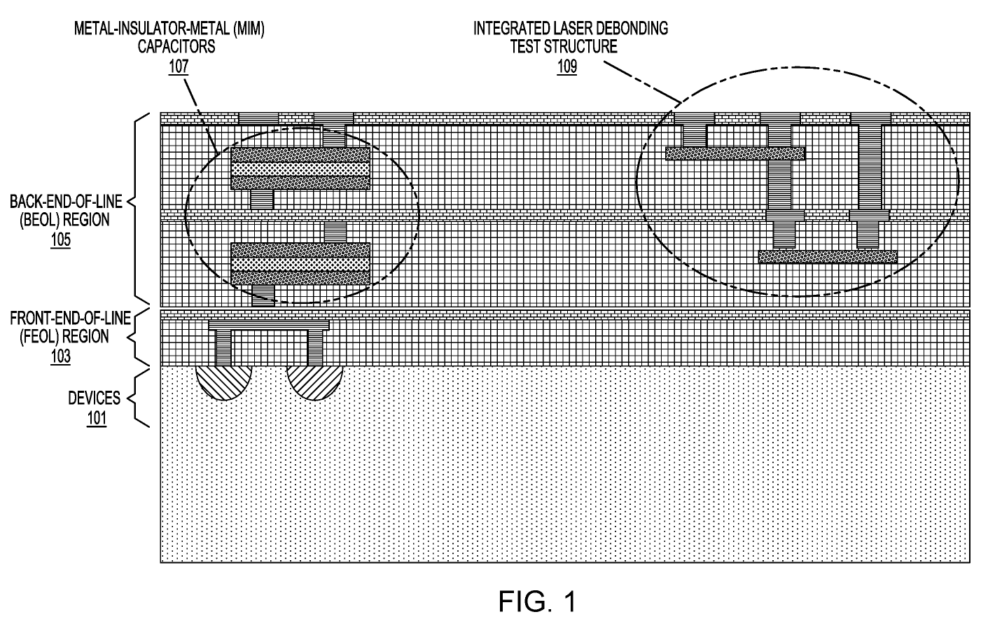

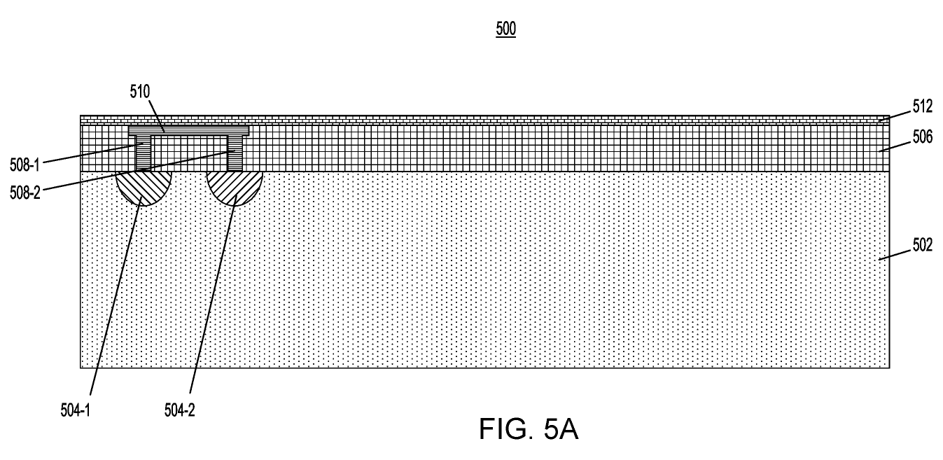

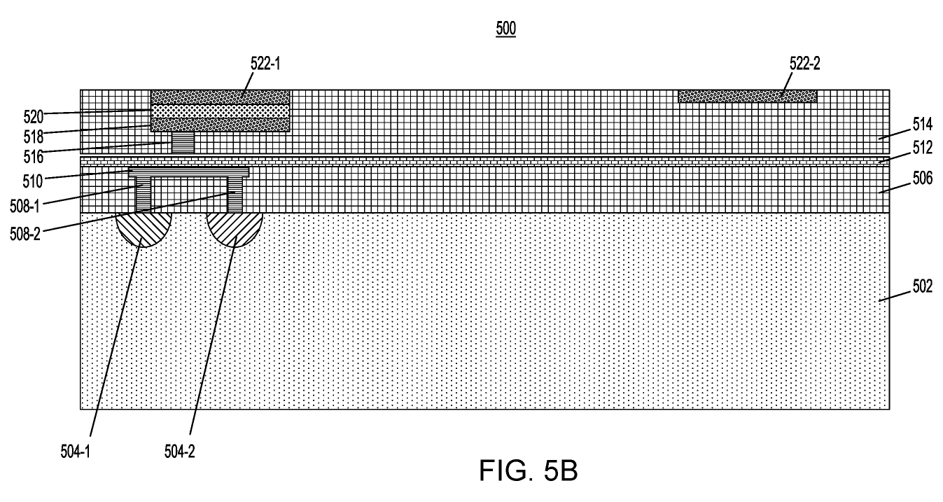

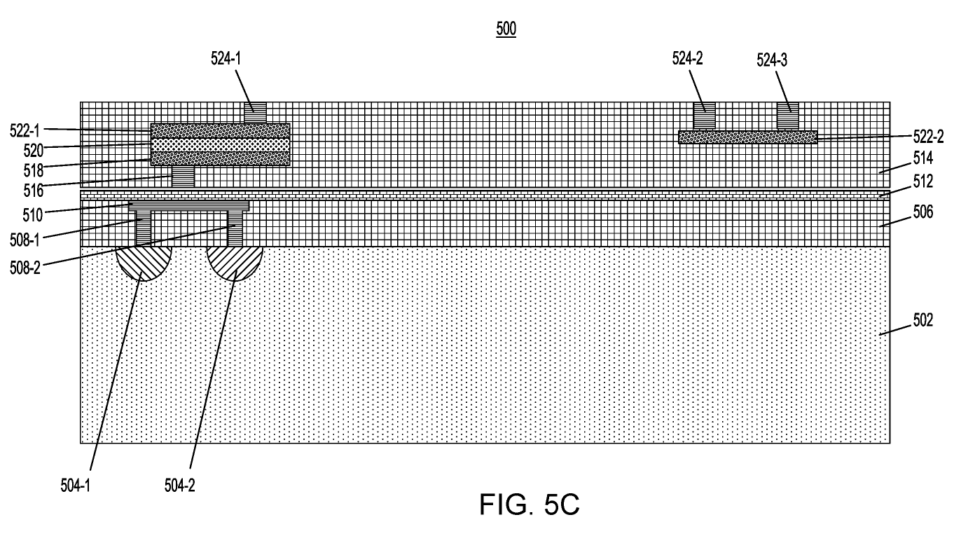

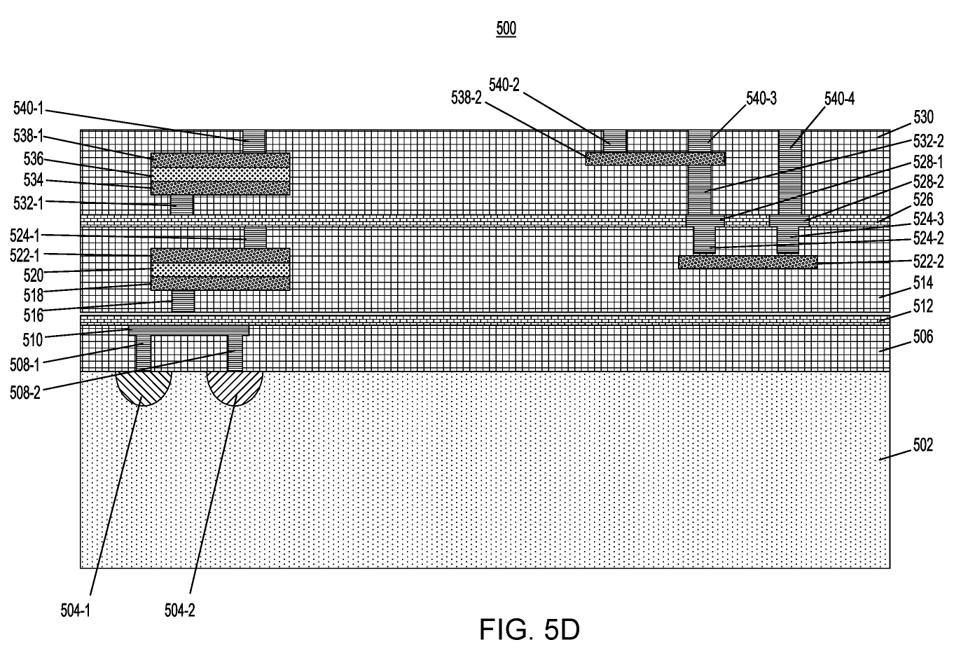

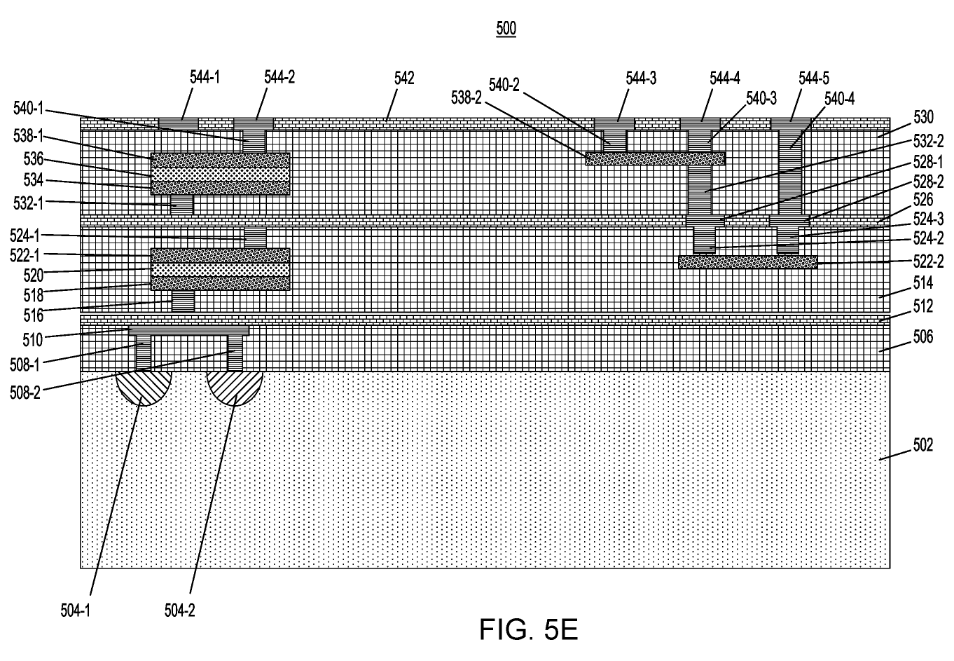

FIG. 1 shows a cross-sectional view of a semiconductor structure 100 including one or more devices 101 formed in a semiconductor substrate (e.g., a silicon (Si) substrate), a FEOL region 103 formed over the devices 101, and a BEOL region 105 formed over the FEOL region 103. The BEOL region 105 includes two MIM capacitors 107, as well as an integrated laser debonding test structure 109. The integrated laser debonding test structure 109 includes two mid-via metal plate layers (e.g., formed between interconnect levels of the BEOL region 105) which are formed at the same time as top or upper metal plate layers of the two MIM capacitors 107. Electrical test probes may be connected to the uppermost interconnects (e.g., testing pads) of the integrated laser debonding test structure 109. A detailed processing flow for forming the semiconductor structure 100 will be described below with respect to FIGS. 5A-5E.

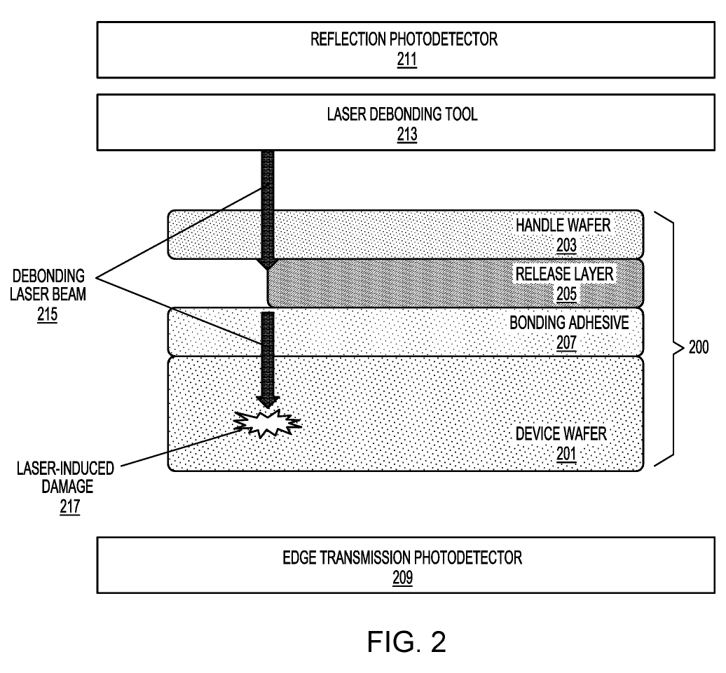

FIG. 2 shows an example of a laser debonding process for a structure 200 including a device wafer 201 (e.g. the semiconductor structure 100 shown in FIG. 1) that is connected to a handle wafer 203 (e.g., a silicon handle wafer or silicon handler) having a release layer 205 coated thereon, where a bonding adhesive 207 connects the device wafer 201 to the release layer 205. The bonding adhesive 207 may be composed of multiple layers, where some of the multiple layers are deposited on the device wafer 201 and some of the multiple layers are deposited on the handle wafer 203, which are then joined using an oxide-oxide bond or other suitable bonding technique. An edge transmission photodetector 209 and a reflection photodetector 211 are placed on opposing sides of the structure 200, and a laser debonding tool 213 applies a debonding laser beam 215 to the structure 200. In the laser debonding process, the debonding laser beam 215 causes laser-induced damage 217 in the device wafer 201.

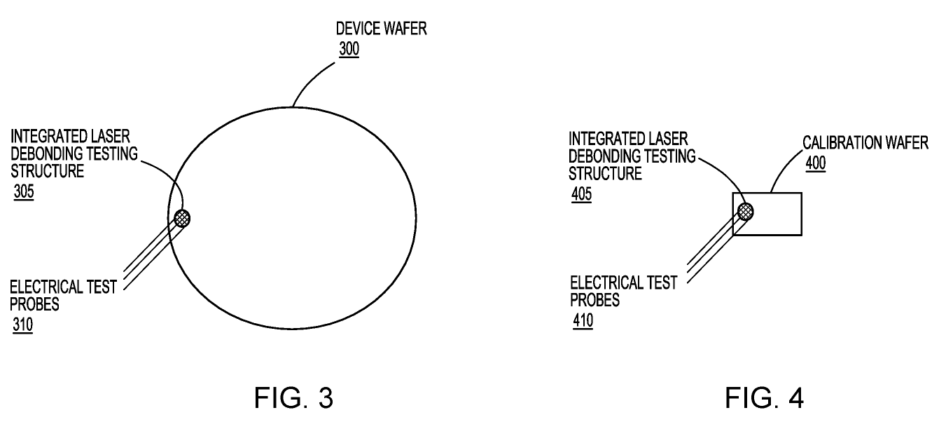

Prior to applying the debonding laser beam 215, the laser debonding tool 213 may be calibrated through a laser scan with measurement of the beam power (e.g., using the edge transmission photodetector 209 and/or the reflection photodetector 211). If the measured beam power is within design specifications, then the laser debonding tool 213 may apply the debonding laser beam 215 to the structure 200. If the measured beam power is not within design specifications, then the beam power and other parameters of the laser debonding tool 213 may be adjusted and the calibration process is repeated. The laser scan with measurement of the beam power may be achieved using a laser debonding test structure (e.g., the integrated laser debonding test structure 109 in the semiconductor structure 100). As will be discussed in further detail below with respect to FIG. 3, the laser debonding test structure may be placed at an edge of the device wafer 201, enabling testing at the edge of the device wafer 201 away from active devices (e.g., devices 101 in the semiconductor structure 100) formed within the device wafer 201.

FIG. 3 shows a top-down view of a device wafer 300 having an integrated laser debonding testing structure 305 formed proximate an edge of the device wafer 300. The device wafer 300 may include active devices (not shown) formed away from the edge of the device wafer 300 where the integrated laser debonding testing structure 305 is formed. Although FIG. 3 shows an example where the integrated laser debonding testing structure 305 is proximate the edge of the device wafer 300, this is not a requirement. The integrated laser debonding testing structure 305 may be located at any desired region of the device wafer 300, or may be distributed across the device wafer 300 (e.g., multiple instances of the integrated laser debonding testing structure 305 may be formed at different areas of the device wafer 300 to help in detecting process non-uniformities or drift of parameters/performance of the laser debonding process). Electrical test probes 310 are connected to the integrated laser debonding testing structure 305, and enable monitoring of the effects of laser beams applied to the device wafer 300 (e.g., as part of a laser debonding tool calibration process, before and after laser debonding, etc.).

FIG. 4 shows a top-down view of a calibration wafer 400 including an integrated laser debonding testing structure 405. The calibration wafer 400 may be used for calibration of a laser debonding tool, before the laser debonding tool is used for performing laser debonding of one or more device wafers (which may or may not include laser debonding test structures as described herein). Electrical test probes 410 are connected to the integrated laser debonding testing structure 405, and enable monitoring of the effects of laser beams applied to the calibration wafer 400 (e.g., as part of a laser debonding tool calibration process, before and after laser debonding, etc.).

In some embodiments, an apparatus includes a laser debonding tool (e.g., the laser debonding tool 213) with one or more power meters for laser detection (e.g., a transmission power meter such as the edge transmission photodetector 209, a reflection power meter such as the reflection photodetector 211, etc.). The laser debonding tool and power meters collectively provide an electrical test station, which may be used at a wafer processing site (e.g., where device wafer 300 with the integrated laser debonding testing structure 305 is subject to laser debonding with one or more laser beams applied by the laser debonding tool) or at a separate calibration site (e.g., where calibration wafer 400 with the integrated laser debonding testing structure 405 is subject to laser debonding with one or more laser beams applied by the laser debonding tool). The electrical test station is configured to monitor the impact of laser debonding processes applied to structures (e.g., the semiconductor structure 100, the device wafer 201, the device wafer 300, the calibration wafer 400, etc.). Artificial intelligence (AI) may be used to perform data trending using information collected from laser debonding test structures as described herein so as to provide guidance for use of laser debonding tools, including calibration and adjustment thereof to reduce or eliminate laser-induced defects in device wafers subject to laser debonding processes.

Testing and calibration may be performed using laser debonding test structures formed on a device or calibration wafer, with electrical test probes being connected to such laser debonding test structures for evaluating the quality of devices in functional wafers before and after application of laser debonding processes. The laser debonding test structures may be located on device wafers (e.g., at an edge thereof) to permit such evaluation while avoiding the impact on passive and active circuits or devices formed in or on the device wafers. The laser debonding test structures can permit pre- and/or post-calibration measurements of the quality and consistency of chips and wafers using various beam power parameters as well as reflectance and transmission measurements. The quality and consistency may be evaluated by monitoring the electrical characteristics of the laser debonding test structures (e.g., built-in test chips) on device wafers during laser debonding tool operation calibration, including monitoring wafer and chip measurements before and/or after laser debonding processes. Laser debonding tools may be calibrated using the laser debonding test structures described herein to acceptable design specifications to support laser debonding of device wafers from handling wafers. The laser debonding test structures thus enable the adjustment of laser power or other control parameters of laser debonding tools to meet design specifications prior to performing laser debonding. Following laser debonding, the laser debonding test structures on chips or wafers may be measured to verify quality of the wafer or dies separated from the wafer (e.g., to sort die for targeted quality and specification levels). AI and data trending may be utilized to provide guidance for chips, wafers or other component use, quality control, designation or binning against target technology and/or product specifications, etc.

FIGS. 5A-5E show a process for forming an integrated laser debonding test structure in a device wafer (e.g., for forming the semiconductor structure 100 shown in FIG. 1). FIG. 5A shows a cross-sectional view of a semiconductor structure 500 including a substrate 502 with a set of devices 504-1 and 504-2 (collectively, devices 504) formed therein. The substrate 502 may be formed of Si or another suitable material. The devices 504 may comprise various active and passive components, including but not limited to transistors, capacitors, resistors, etc. The semiconductor structure 500 also includes an interlayer dielectric (ILD) layer 506 and FEOL contacts 508-1 and 508-2 (collectively, FEOL contacts 508) formed to the devices 504-1 and 504-2, respectively. A FEOL interconnect 510 is also shown connecting the FEOL contacts 508-1 and 508-2. An additional ILD layer 512 is formed over the ILD layer 506. The ILD layers 506 and 512 may be formed of the same or different materials. In some embodiments, the ILD layer 506 is formed of silicon dioxide (SiO₂) and the ILD layer 512 is formed of silicon carbon nitride (SiCN). It should be noted that FIGS. 5A-5E show just one example of forming an integrated laser debonding test structure in a device wafer, and that embodiments are not limited to or tied to any specific FEOL devices and associated structures. Rather, FIGS. 5A-5E illustrate that there may be FEOL devices and various dielectric and metal interconnects used in semiconductor fabrication processes.

FIG. 5B shows a cross-sectional view of the semiconductor structure 500 of FIG. 5A following formation of a first interconnect level of a BEOL region. This includes an ILD layer 514, in which a via 516 is formed. The ILD layer 514 may be formed of the same material as the ILD layer 506. A metal material is deposited and patterned to provide a first (bottom) metal plate 518 for a first MIM capacitor. An insulator material is then deposited and patterned to provide an insulator 520 for the first MIM capacitor, followed by deposition and patterning of a metal material to provide a second (top) metal plate 522-1 for the first MIM capacitor, as well as a first testable metal plate 522-2 for a laser debonding test structure. The second metal plate 522-1 and the first testable metal plate 522-2 are advantageously formed at the same time, thus providing a low-cost on-chip solution for forming the laser debonding test structure with the same fabrication process as the first MIM capacitor.

FIG. 5C shows a cross-sectional view of the semiconductor structure 500 of FIG. 5B following formation of additional material for the ILD layer 514, and following formation of vias 524-1, 524-2 and 524-3 (collectively, vias 524). The first MIM capacitor (including the first metal plate 518, the insulator 520 and the second metal plate 522-1) is a “mid-via” MIM capacitor as it is formed between the vias 516 and 524-1 between different metal interconnect levels of the BEOL region. Mid-via may refer to a metal plate that has a via passing through it, or a metal plate that exists between two BEOL layers or levels with a via that lands on the metal plate or passes through the metal plate. The first testable metal plate 522-2 is also a “mid-via” metal plate, formed with the same processing as that used for the second metal plate 522-1 of the first MIM capacitor. It should be noted, however, that a testable metal plate for a laser debonding test structure may alternatively be formed with the same processing as that used for the first metal plate 518 of the first MIM capacitor. The vias 524-2 and 524-3 connect to the first testable metal plate 522-2.

FIG. 5D shows a cross-sectional view of the semiconductor structure 500 of FIG. 5C following formation of a second MIM capacitor and another testable metal plate of the laser debonding test structure. An ILD layer 526 is formed, which may be the same material as the ILD layer 512. Interconnects 528-1 and 528-2 (collectively, interconnects 528) are formed in the ILD layer 526, contacting the underlying vias 524-2 and 524-3, respectively. An ILD layer 530 is then formed, which may be the same material as the ILD layers 506 and 514. Vias 532-1, 532-2 and 532-3 (collectively, vias 532) are formed, followed by formation of a first (bottom) metal plate 534 for the second MIM capacitor, an insulator 536 for the second MIM capacitor, and a second (top) metal plate 538-1 for the second MIM capacitor and a second testable metal plate 538-2 for the laser debonding test structure. The via 532-1 contacts the first metal plate 534 of the second MIM capacitor. The via 532-2 contacts the interconnect 528-1 and the second testable metal plate 538-2. The via 532-3 contacts the interconnect 528-2. The second metal plate 538-1 for the second MIM capacitor and the second testable metal plate 538-2 are formed using the same processing, similar to the second metal plate 522-1 and the first testable metal plate 522-2. Vias 540-1, 540-2, 540-3 and 540-4 (collectively, vias 540) are then formed. The via 540-1 contacts the second metal plate 538-1 of the second MIM capacitor, while the vias 540-2 and 540-3 contact the second testable metal plate 538-2. The via 540-4 contacts the via 532-3, which contacts the interconnect 528-2.

FIG. 5E shows a cross-sectional view of the semiconductor structure 500 of FIG. 5D following formation of a top of the BEOL region. This includes formation of ILD layer 542, which may be the same material as the ILD layers 526 and 512. Interconnects 544-1, 544-2, 544-3, 544-4 and 544-5 (collectively, interconnects 544) are formed in the ILD layer 542. The interconnect 544-1 connects to one or more underlying vias and interconnects (not shown) in the BEOL region. The interconnect 544-2 contacts the via 540-1, which contacts the second metal plate 538-1 of the second MIM capacitor. The interconnects 544-3 and 544-4 contact the vias 540-2 and 540-3, which contact the second testable metal plate 538-2, while the interconnect 544-5 contacts the via 540-4, which contacts the first testable metal plate 522-2 through the via 532-3, the interconnect 528-2 and the via 524-3. The interconnects 544-3, 544-4 and 544-5 may be referred to as test pads of the laser debonding test structure. Electrical testing probes may contact the test pads of the laser debonding test structure for testing (before, during and/or after a laser debonding process that the semiconductor structure 500 is subject to).

It should be noted that the although the semiconductor structure 500 includes a laser debonding test structure with just two testable metal plates 522-2 and 538-2, this is not a requirement. A laser debonding test structure may include just a single testable metal plate, or three or more testable metal plates. Further, laser debonding test structures may include serpentine testable metal plate structures for a given testable metal plate, or there may be chains of testable metal plates (e.g., on a given MIM level) that are linked together using other metal interconnects, thus enabling statistical analysis to be performed, including where different length chains are analyzed for defects. Further, while efficiencies are achieved with formation of the testable metal plates at the same time as metal plates of mid-via MIM capacitors, this is not a requirement. One or more testable metal plates of a laser debonding test structure may be formed between metal interconnect levels of a BEOL region (and potentially within the FEOL region) where MIM capacitors are not formed.

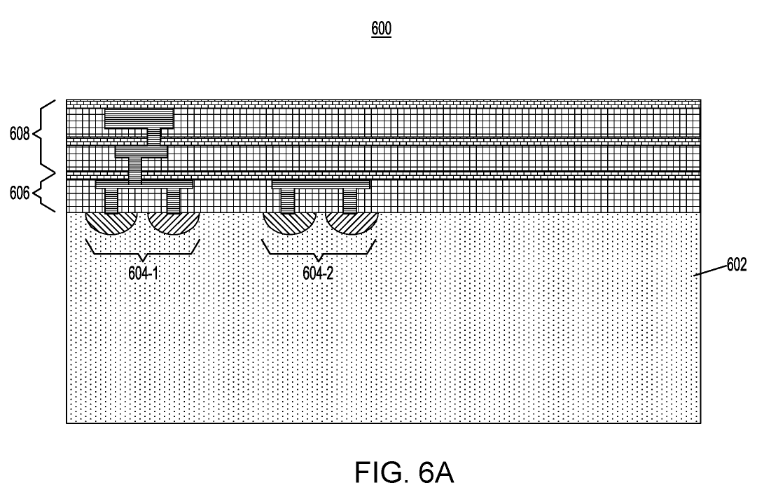

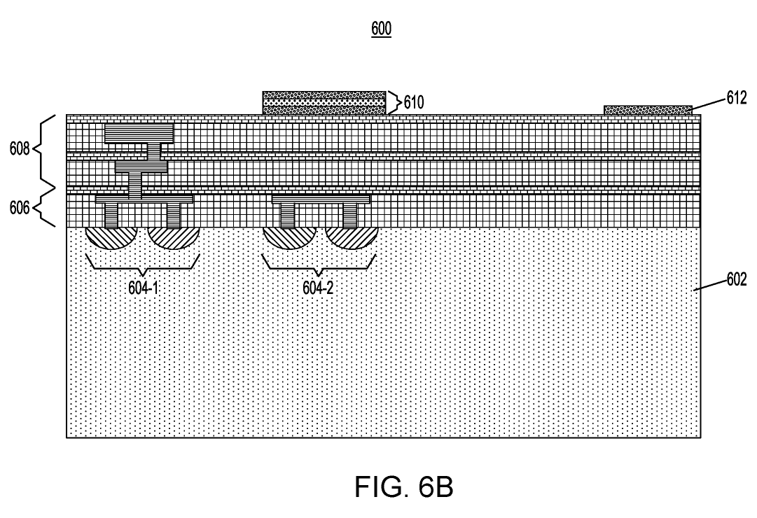

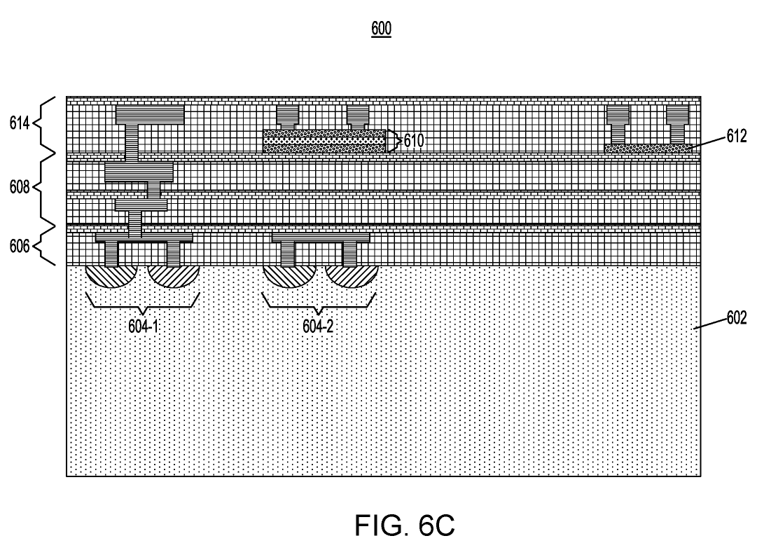

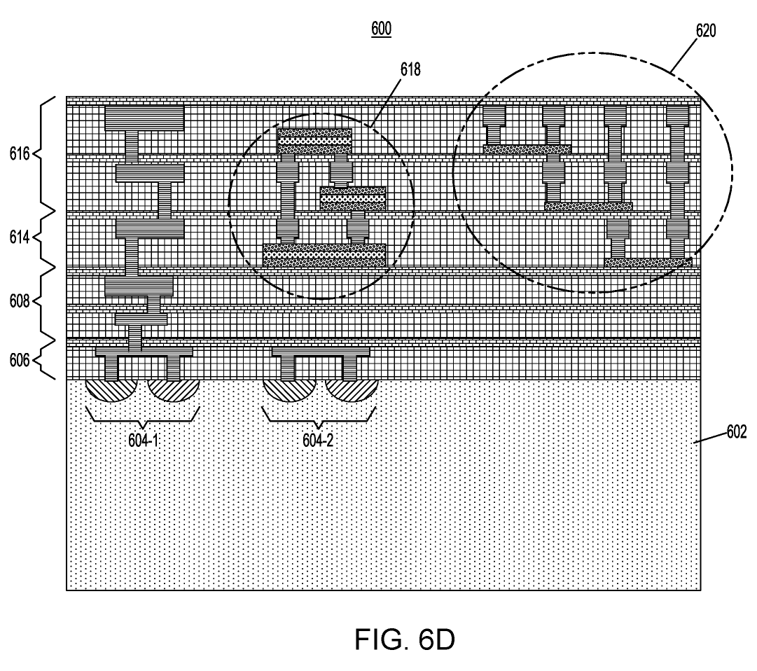

FIGS. 6A-6D show a process flow for forming a laser debonding test structure in a device wafer, where the device wafer includes a stacked MIM capacitor in a BEOL region and the laser debonding test structure includes three testable metal plates between different metal interconnect levels of the BEOL region.

FIG. 6A shows a cross-sectional view of a semiconductor structure 600 including a substrate 602 (e.g., formed of silicon or another suitable material) with sets of active devices 604-1 and 604-2 (collectively, active devices 604) formed therein. The semiconductor structure 600 also includes a FEOL region 606 with contacts and interconnects for the active devices 604 formed within an ILD layer. The semiconductor structure 600 also includes two levels 608 of a BEOL region, which include contacts and interconnects formed within ILD layers which connect to underlying contacts and interconnects in the FEOL region 606 to the active device 604-1 below.

FIG. 6B shows a cross-sectional view of the semiconductor structure 600 of FIG. 6A following formation of MIM capacitor 610 and a testable metal plate 612. The MIM capacitor 610 includes first (bottom) and second (top) metal plates separated by an insulating layer. Here, the testable metal plate 612 is formed at the same time as the first or bottom metal plate of the MIM capacitor 610 (as compared with the process flow illustrated in FIGS. 5A-5E, where the testable metal plates 522-2 and 538-2 are formed at the same time as second or top metal plates 522-1 and 538-1 of first and second MIM capacitors). It should be appreciated, however, that the testable metal plate 612 may alternatively be formed at the same time as the second or top metal plate of the MIM capacitor. In some embodiments, the testable metal plate 612 is formed together with whichever of the metal plates of the MIM capacitor 610 is thinner (if they are of different thicknesses, which is not a requirement), as thinner metal layers may have a higher sensitivity to laser impact or damage.

FIG. 6C shows a cross-sectional view of the semiconductor structure 600 of FIG. 6B following formation of vias and interconnects within a level 614 of the BEOL region where the MIM capacitor 610 and the testable metal plate 612 are formed. The vias and interconnects may be formed using copper damascene or other suitable processing. The vias and interconnects in the level 614 of the BEOL region (i) connect to underlying interconnects and contacts in the levels 608 of the BEOL region and (ii) connect to the second or top plate of the MIM capacitor 610 and the testable metal plate 612.

FIG. 6D shows a cross-sectional view of the semiconductor structure 600 of FIG. 6C following formation of additional levels 616 of the BEOL region where additional MIM capacitors and testable metal plates are formed (e.g., using similar processing as that described above with respect to formation of the MIM capacitor 610 and the testable metal plate 612), along with vias and interconnects which (i) connect to underlying interconnects and contacts in the level 614 of the BEOL region (ii) interconnect the additional MIM capacitors with the MIM capacitor 610 to provide a stacked MIM capacitor structure 618, and (iii) interconnect the additional testable metal plates with the testable metal plate 612 to provide a laser debonding test structure 620.

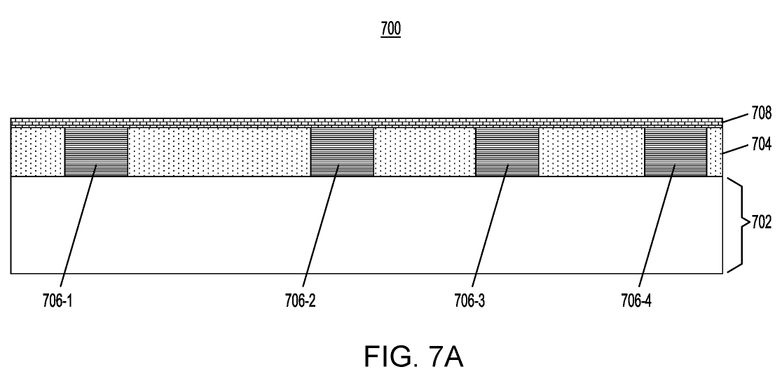

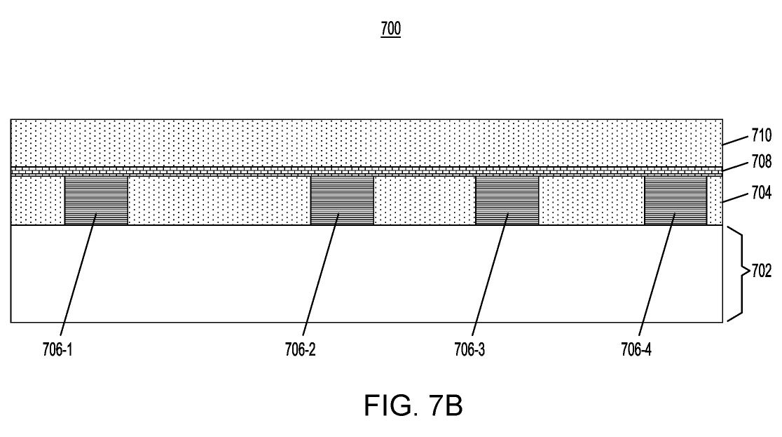

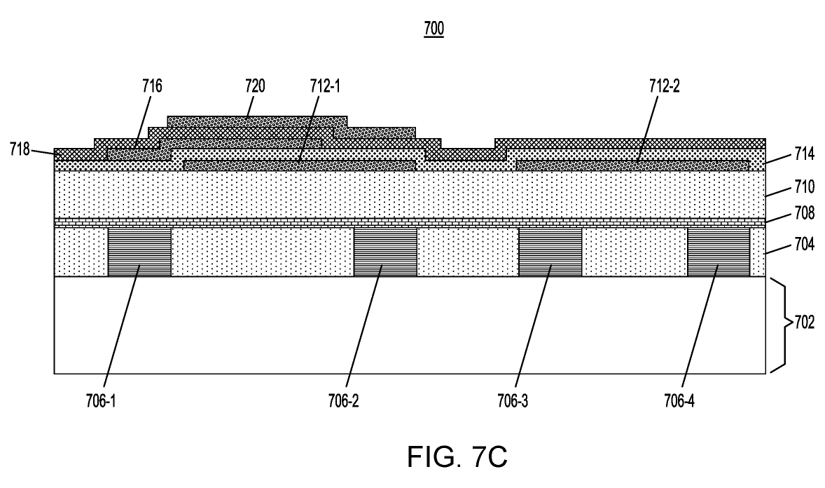

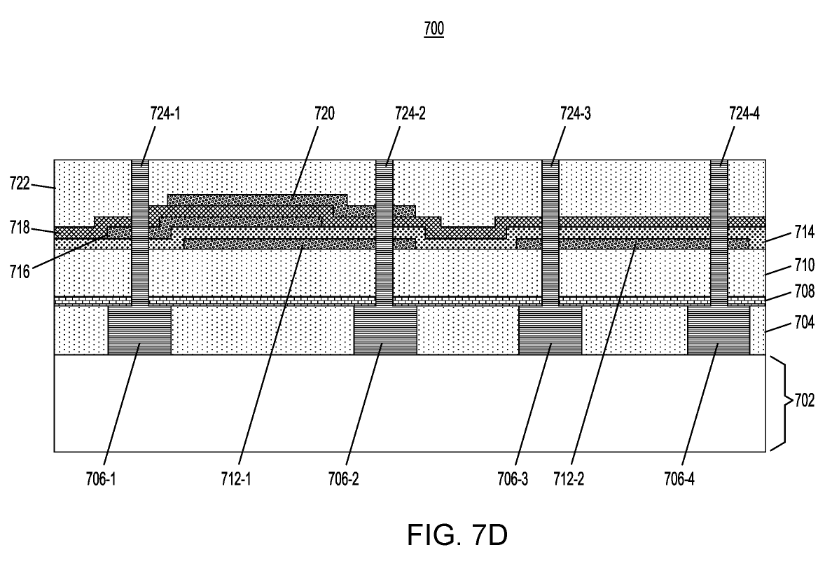

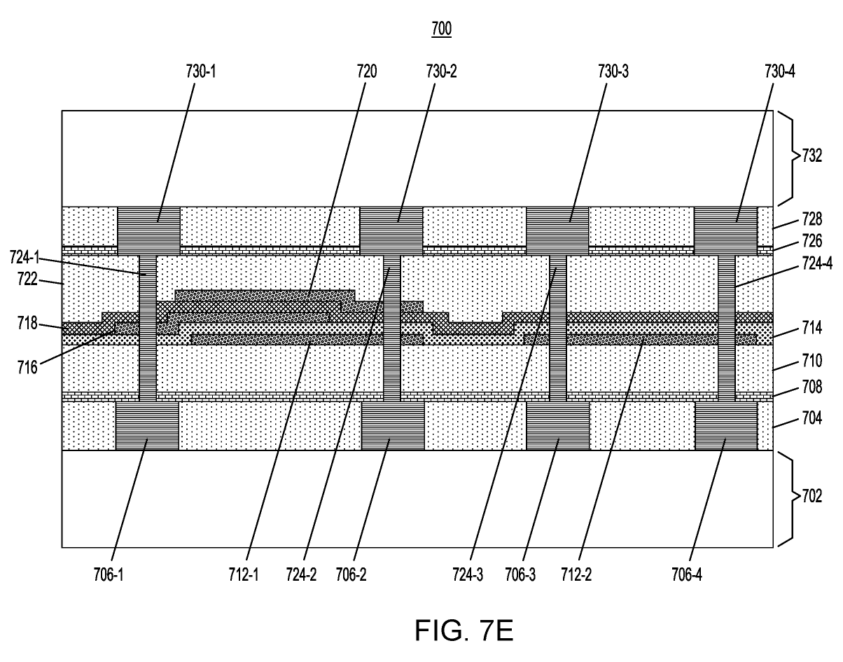

FIGS. 7A-7E show another process flow for forming an integrated laser debonding test structure in a device wafer.

FIG. 7A shows a cross-sectional view of a semiconductor structure 700, including a substrate 702 in which one or more devices (not shown) are formed, along with an ILD layer 704 formed over the substrate 702. The ILD layer 704 may be formed of SiO₂ or another suitable material. A set of contacts 706-1, 706-2, 706-3 and 706-4 (collectively, contacts 706) are formed in the ILD layer 704. The contacts 706 connect to different components (not explicitly shown) formed in the substrate 702. The contacts 706 may be formed of Cu or another suitable material. Another ILD layer 708 is formed over the contacts 706 and the ILD layer 704. The ILD layer 708 may be formed of SiCN or another suitable material.

FIG. 7B shows a cross-sectional view of the semiconductor structure 700 of FIG. 7A following formation of another ILD layer 710 over the ILD layer 708. The ILD layer 710 may be the same material as the ILD layer 704.

FIG. 7C shows a cross-sectional view of the semiconductor structure 700 of FIG. 7B following formation of a “mid-via” MIM capacitor and a testable metal plate for a laser debonding test structure. A metal material is deposited over the ILD layer 710, followed by patterning of a mask layer and removal of portions of the metal material, with remaining portions of the metal material providing a first (bottom) metal plate 712-1 for the MIM capacitor and a testable metal plate 712-2 for the laser debonding test structure. An insulator layer 714 is then deposited over the ILD layer 710, the first metal plate 712-1 and the testable metal plate 712-2. The insulator layer 714 may be formed of a high-k dielectric material. A metal material is then deposited over the insulator layer 714, followed by patterning of a mask layer and removal of portions of the metal material, with the remaining portion of the metal material providing a second (middle) metal plate 716 for the MIM capacitor. Another insulator layer 718 is then deposited over the second metal plate 716 and the underlying insulator layer 714. The insulator layer 718 may be formed of the same or a different high-k material as the insulator layer 714. A metal material is then deposited over the insulator layer 718, followed by patterning of a mask layer and removal of portions the metal material, with the remaining portion of the metal material providing a third (top) metal plate 720 for the MIM capacitor. In some embodiments, the first metal plate 712-1 (as well as the testable metal plate 712-2), the second metal plate 716 and the third metal plate 720 are formed of the same metal material (e.g., one of Ti, TiN, Ta, TaN, etc.). In other embodiments, at least one of the first metal plate 712-1 (and the testable metal plate 712-2), the second metal plate 716 and the third metal plate 720 are formed of a different metal material than other ones of the first metal plate 712-1, the second metal plate 716 and the third metal plate 720.

FIG. 7D shows a cross-sectional view of the semiconductor structure 700 of FIG. 7C following formation of an additional ILD layer 722, which may be the same material as the ILD layers 710 and 704, along with formation of vias 724-1, 724-2, 724-3 and 724-4 (collectively, vias 724) through ILD layer 710 and underlying layers down to connect to the vias 706-1, 706-2, 706-3 and 706-4, respectively. The vias 724 may be formed of Cu or another suitable material, using damascene or other suitable processing. In the semiconductor structure 700, the vias 724 are formed through the MIM capacitor and the testable metal plate 712-2 of the laser debonding test structure. This is in contrast with the structures shown in FIGS. 1, 5A-5E and 6A-6D, where vias connect to top and bottom surfaces of the MIM capacitors and testable metal plates of the laser debonding test structures rather than being formed through the MIM capacitors and the testable metal plates of the laser debonding test structures.

FIG. 7E shows a cross-sectional view of the semiconductor structure 700 of FIG. 7D following formation of ILD layers 726 and 728, and formation of vias 730-1, 730-2, 730-3 and 730-4 (collectively, vias 730) through the ILD layers 728 and 726 to connect to the underlying vias 724-1, 724-2, 724-3 and 724-4, respectively. The vias 730 may be formed of Cu or another suitable material, using damascene or other suitable processing. Additional levels of a BEOL region 732 are then formed over the structure. The additional levels of the BEOL region 732 may include additional MIM capacitors and/or testable metal plates of the laser debonding test structure.

In the examples of FIG. 1, 5A-5E, 6A-6D and 7A-7E, testable metal plates of laser debonding test structures are formed adjacent to MIM capacitors between any given two metal interconnect levels of a BEOL region. The testable metal plates of the laser debonding test structure can be formed concurrently with any of the metal layers of the MIM capacitors (e.g., bottom, middle or top metal plates), where the MIM capacitors may include two or more metal layers. The metal plates of the MIM capacitors, as well as the testable metal plates of the laser debonding test structure, can be formed using any suitable approach. In some embodiments, a subtractive process is used (e.g., blanket metal deposition and patterning). In other embodiments, a damascene process is used (e.g., filling a trench and planarizing). It should be noted that the different metal plates of a MIM capacitor (and, correspondingly, different testable metal plates of a laser debonding test structure), can be formed of the same or different metal materials. In some embodiments, multiple ones of the metal plates of one or more MIM capacitors and/or a laser debonding test structure have the same metal composition. In other embodiments, two or more of the metal plates of one or more MIM capacitors and/or a laser debonding test structure have different metal compositions.

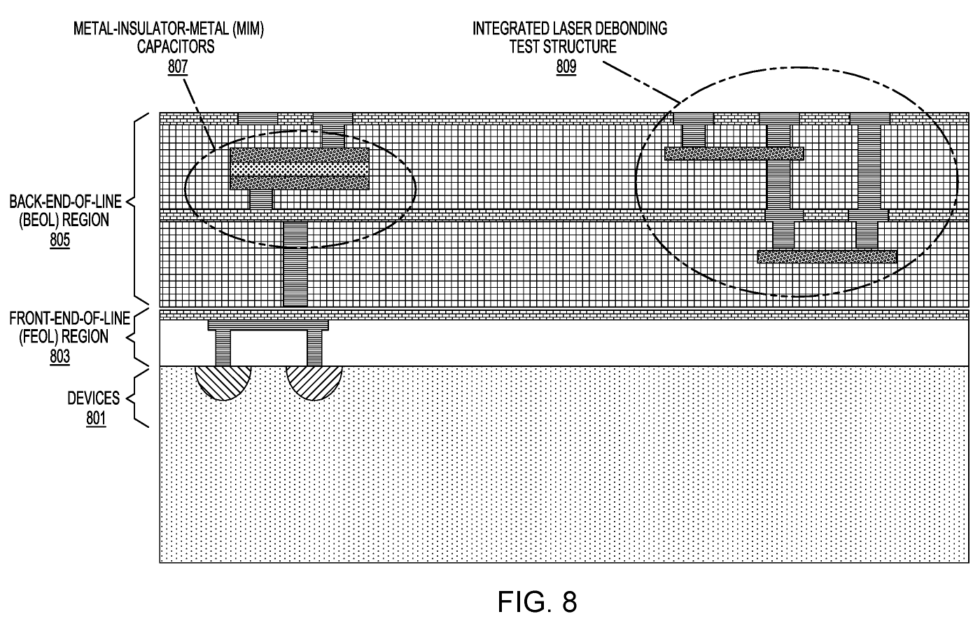

As discussed above, vias which are used to connect to testable metal plates of a laser debonding test structure may pass through the testable metal plates of the laser debonding test structure, or may terminate on the testable metal plates of the laser debonding test structure (e.g., on top and/or bottom surfaces of testable metal plates of the laser debonding test structure). Further, a laser debonding test structure may include testable metal plates in some but not all levels of a BEOL region. Not all layers of the BEOL region will necessarily include a MIM capacitor. In some embodiments, testable metal plates of the laser debonding test structure are only formed in layers of the BEOL region in which a MIM capacitor is formed, though not necessarily in every layer of the BEOL region in which a MIM capacitor is formed. In other embodiments, at least one testable metal plate is formed in a layer of the BEOL region in which a MIM capacitor is not formed. This is illustrated in FIG. 8, which shows a cross-sectional view of a semiconductor structure 800 including one or more devices 801 formed in a semiconductor substrate (e.g., a Si substrate), a FEOL region 803 formed over the devices 801, and a BEOL region 805 formed over the FEOL region 803. The BEOL region 805 includes one MIM capacitor 807, as well as an integrated laser debonding test structure 809. The integrated laser debonding test structure 809 includes two mid-via metal plate layers (e.g., formed between interconnect levels of the BEOL region 805), where one of the mid-via metal plate layers (the top or upper mid-via metal plate layer) is formed at the same time as a top or upper metal plate layer of the MIM capacitor 807, with the other mid-via metal plate layer of the integrated laser debonding test structure being formed in a level of the BEOL region 805 which does not include a MIM capacitor. Electrical test probes may be connected to the uppermost interconnects (e.g., testing pads) of the integrated laser debonding test structure 809.

According to an aspect of the invention, a semiconductor structure includes a BEOL region including a first level of metal interconnects and a second level of metal interconnects separated by at least one ILD layer, and a laser debonding test structure disposed in the BEOL region. The laser debonding test structure includes a testable metal plate layer disposed within the at least one ILD layer between the first level of metal interconnects and the second level of metal interconnects, a set of test pads, and a set of vias, at least a subset of the set of vias extending from at least one test pad in the set of test pads to the testable metal plate layer disposed within the at least one ILD layer between the first level of metal interconnects and the second level of metal interconnects.

In embodiments, the semiconductor structure also includes a MIM capacitor disposed within the at least one ILD layer separating the first level of metal interconnects and the second level of metal interconnects, the MIM capacitor including a first metal capacitor plate and a second metal capacitor plate separated by an insulating layer, wherein the testable metal plate layer of the laser debonding test structure is substantially coplanar with the first metal capacitor plate. The first metal capacitor plate may have a first thickness and the second metal capacitor plate may have a second thickness, the second thickness being greater than the first thickness.

In embodiments, the BEOL region further includes a third level of metal interconnects separated from the second level of metal interconnects by at least one additional ILD layer, the laser debonding test structure further including an additional testable metal plate layer disposed within the at least one additional ILD layer between the second level of metal interconnects and the third level of metal interconnects. At least one additional via in the set of vias may extend from at least one additional test pad in the set of test pads to the additional testable metal plate layer disposed within the at least one additional ILD layer between the second level of metal interconnects and the third level of metal interconnects. At least one additional via in the set of vias may extend from at least one additional test pad in the set of test pads through the testable metal plate layer and to the additional testable metal plate layer disposed within the at least one additional ILD layer between the second level of metal interconnects and the third level of metal interconnects. The semiconductor structure may further include a first MIM capacitor disposed within the at least one ILD layer separating the first level of metal interconnects and the second level of metal interconnects and a second MIM capacitor disposed within the at least one additional ILD layer, wherein each of the first MIM capacitor and the second MIM capacitor includes a first metal capacitor plate and a second metal capacitor plate separated by an insulating layer. The testable metal plate layer of the laser debonding test structure may be substantially coplanar with one of the first metal capacitor plate and the second metal capacitor plate of the first MIM capacitor, and the additional testable metal plate layer of the laser debonding test structure may be substantially coplanar with one of the first metal capacitor plate and the second metal capacitor plate of the second MIM capacitor. The first MIM capacitor and the second MIM capacitor may be interconnected with a set of vias to provide a stacked MIMcapacitor structure.

In embodiments, the BEOL region is disposed over a FEOL region of a semiconductor wafer, the laser debonding test structure being disposed proximate an outer edge of the semiconductor wafer. The FEOL region of the semiconductor wafer may include one or more active device components in an inner region of the semiconductor wafer spaced apart from the outer edge of the semiconductor wafer.

In embodiments, the testable metal plate layer is one of Ta, TaN, Ti and TiN.

In embodiments, the testable metal plate layer has a thickness of about 10 to 100nm.

According to another aspect of the invention, a semiconductor structure includes a first level of metal interconnects, at least one ILD layer disposed over the first level of metal interconnects, a second level of metal interconnects disposed over the at least one ILD layer, a MIM capacitor disposed within the at least one ILD layer, the MIM capacitor including a first metal capacitor plate and a second metal capacitor plate separated by an insulating layer, a testable metal plate layer of a laser debonding test structure disposed within the at least one ILD layer, the testable metal plate layer being spaced apart from and substantially coplanar with one of the first metal capacitor plate and the second metal capacitor plate, and one or more vias extending from the testable metal plate layer through the at least one ILD layer to a metal interconnect in the second level of metal interconnects.

In embodiments, the metal interconnect in the second level of metal interconnects provides a testing pad of the laser debonding test structure.

In embodiments, the one of the first metal capacitor plate and the second metal capacitor plate is a thinner one of the first metal capacitor plate and the second metal capacitor plate.

In embodiments, the semiconductor structure further includes at least one additional ILD layer disposed over the second level of metal interconnects, a third level of metal interconnects disposed over the at least one additional ILD layer, an additional testable metal plate layer of the laser debonding test structure disposed within the at least one additional ILD layer, and at least one additional via extending from the additional testable metal plate layer through the at least one additional ILD layer to a metal interconnect in the third level of metal interconnects. The semiconductor structure may further include an additional MIM capacitor disposed within the at least one additional ILD layer, the additional MIM capacitor including a third metal capacitor plate and a fourth metal capacitor plate separated by an additional insulating layer, wherein the additional testable metal plate layer is spaced apart from and substantially coplanar with one of the third metal capacitor plate and the fourth metal capacitor plate.

According to another aspect of the invention an integrated circuit includes a semiconductor structure including an FEOL region including one or more active device components, a BEOL region disposed over the FEOL region, the BEOL region including a first level of metal interconnects and a second level of metal interconnects separated by at least one ILD layer, and a laser debonding test structure disposed in the BEOL region. The laser debonding test structure including a testable metal plate layer disposed within the at least one ILD layer between the first level of metal interconnects and the second level of metal interconnects, a set of test pads, and a set of vias, at least a subset of vias in the set of vias extending from at least one test pad in the set of test pads to the testable metal plate layer disposed within the at least one ILD layer between the first level of metal interconnects and the second level of metal interconnects.

In embodiments, the semiconductor structure further includes a MIM capacitor disposed within the at least one ILD layer separating the first level of metal interconnects and the second level of metal interconnects, the MIM capacitor including a first metal capacitor plate and a second metal capacitor plate separated by an insulating layer, wherein the testable metal plate layer of the laser debonding test structure is substantially coplanar with the first metal capacitor plate.

In embodiments, the laser debonding test structure is disposed proximate an outer edge of the semiconductor structure, and the FEOL region includes one or more active device components in an inner region of the semiconductor structure spaced apart from the outer edge of the semiconductor structure.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, complementary metal-oxide-semiconductor (CMOS) transistors, metal-oxide-semiconductor field-effect transistors (MOSFETs), and/or FinFETs. By way of non-limiting example, the semiconductor devices can include, but are not limited to CMOS, MOSFET, and FinFET devices, and/or semiconductor devices that use CMOS, MOSFET, and/or FinFET technology.

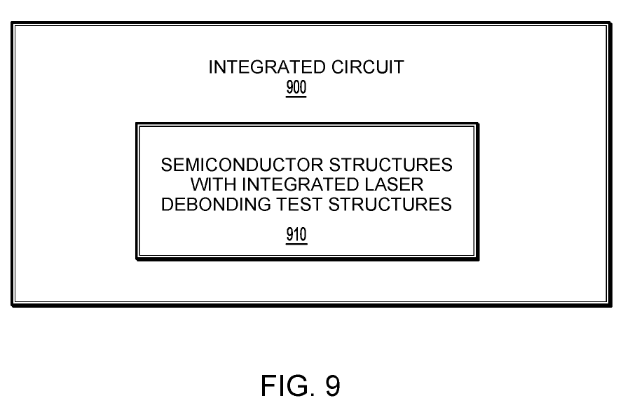

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor. FIG. 9 shows an example integrated circuit 900 which includes one or more semiconductor structures 910 with integrated laser debonding test structures.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. With respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a back-end-of-line region comprising a first level of metal interconnects and a second level of metal interconnects separated by at least one interlayer dielectric layer;
a laser debonding test structure disposed in the back-end-of-line region, the laser debonding test structure comprising:
a testable metal plate layer disposed within the at least one interlayer dielectric layer between the first level of metal interconnects and the second level of metal interconnects;
a set of test pads; and
a set of vias, at least a subset of the set of vias extending from at least one test pad in the set of test pads to the testable metal plate layer disposed within the at least one interlayer dielectric layer between the first level of metal interconnects and the second level of metal interconnects.

2. The semiconductor structure of claim 1, further comprising a metal-insulator-metal capacitor disposed within the at least one interlayer dielectric layer separating the first level of metal interconnects and the second level of metal interconnects, the metal-insulator-metal capacitor comprising a first metal capacitor plate and a second metal capacitor plate separated by an insulating layer, wherein the testable metal plate layer of the laser debonding test structure is substantially coplanar with the first metal capacitor plate.

3. The semiconductor structure of claim 2, wherein the first metal capacitor plate has a first thickness and the second metal capacitor plate has a second thickness, the second thickness being greater than the first thickness.

4. The semiconductor structure of claim 1, wherein the back-end-of-line region further comprises a third level of metal interconnects separated from the second level of metal interconnects by at least one additional interlayer dielectric layer, the laser debonding test structure further comprising an additional testable metal plate layer disposed within the at least one additional interlayer dielectric layer between the second level of metal interconnects and the third level of metal interconnects.

5. The semiconductor structure of claim 4, wherein at least one additional via in the set of vias extends from at least one additional test pad in the set of test pads to the additional testable metal plate layer disposed within the at least one additional interlayer dielectric layer between the second level of metal interconnects and the third level of metal interconnects.

6. The semiconductor structure of claim 4, wherein at least one additional via in the set of vias extends from at least one additional test pad in the set of test pads through the testable metal plate layer and to the additional testable metal plate layer disposed within the at least one additional interlayer dielectric layer between the second level of metal interconnects and the third level of metal interconnects.

7. The semiconductor structure of claim 4, further comprising:
a first metal-insulator-metal capacitor disposed within the at least one interlayer dielectric layer separating the first level of metal interconnects and the second level of metal interconnects; and
a second metal-insulator-metal capacitor disposed within the at least one additional interlayer dielectric layer;
wherein each of the first metal-insulator-metal capacitor and the second metal-insulator-metal capacitor comprises a first metal capacitor plate and a second metal capacitor plate separated by an insulating layer;
wherein the testable metal plate layer of the laser debonding test structure is substantially coplanar with one of the first metal capacitor plate and the second metal capacitor plate of the first metal-insulator-metal capacitor; and
wherein the additional testable metal plate layer of the laser debonding test structure is substantially coplanar with one of the first metal capacitor plate and the second metal capacitor plate of the second metal-insulator-metal capacitor.

8. The semiconductor structure of claim 7, wherein the first metal-insulator-metal capacitor and the second metal-insulator-metal capacitor are interconnected with a set of vias to provide a stacked metal-insulator-metal capacitor structure.

9. The semiconductor structure of claim 1, wherein the back-end-of-line region is disposed over a front-end-of-line region of a semiconductor wafer, the laser debonding test structure being disposed proximate an outer edge of the semiconductor wafer.

10. The semiconductor structure of claim 9, wherein the front-end-of-line region of the semiconductor wafer comprises one or more active device components in an inner region of the semiconductor wafer spaced apart from the outer edge of the semiconductor wafer.

11. The semiconductor structure of claim 1, wherein the testable metal plate layer is one of tantalum, tantalum nitride, titanium and titanium nitride.

12. The semiconductor structure of claim 1, wherein the testable metal plate layer has a thickness of about 10 to 100 nanometers.

13. A semiconductor structure comprising:
a first level of metal interconnects;
at least one interlayer dielectric layer disposed over the first level of metal interconnects;
a second level of metal interconnects disposed over the at least one interlayer dielectric layer;
a metal-insulator-metal capacitor disposed within the at least one interlayer dielectric layer, the metal-insulator-metal capacitor comprising a first metal capacitor plate and a second metal capacitor plate separated by an insulating layer;
a testable metal plate layer of a laser debonding test structure disposed within the at least one interlayer dielectric layer, the testable metal plate layer being spaced apart from and substantially coplanar with one of the first metal capacitor plate and the second metal capacitor plate; and
one or more vias extending from the testable metal plate layer through the at least one interlayer dielectric layer to a metal interconnect in the second level of metal interconnects.

14. The semiconductor structure of claim 13, wherein the metal interconnect in the second level of metal interconnects provides a testing pad of the laser debonding test structure.

15. The semiconductor structure of claim 13, wherein said one of the first metal capacitor plate and the second metal capacitor plate comprises a thinner one of the first metal capacitor plate and the second metal capacitor plate.

16. The semiconductor structure of claim 13, further comprising:
at least one additional interlayer dielectric layer disposed over the second level of metal interconnects;
a third level of metal interconnects disposed over the at least one additional interlayer dielectric layer;
an additional testable metal plate layer of the laser debonding test structure disposed within the at least one additional interlayer dielectric layer; and
at least one additional via extending from the additional testable metal plate layer through the at least one additional interlayer dielectric layer to a metal interconnect in the third level of metal interconnects.

17. The semiconductor structure of claim 16, further comprising an additional metal-insulator-metal capacitor disposed within the at least one additional interlayer dielectric layer, the additional metal-insulator-metal capacitor comprising a third metal capacitor plate and a fourth metal capacitor plate separated by an additional insulating layer, wherein the additional testable metal plate layer is spaced apart from and substantially coplanar with one of the third metal capacitor plate and the fourth metal capacitor plate.

18. An integrated circuit comprising:
a semiconductor structure comprising:
a front-end-of-line region comprising one or more active device components;
a back-end-of-line region disposed over the front-end-of-line region, the back-end-of-line region comprising a first level of metal interconnects and a second level of metal interconnects separated by at least one interlayer dielectric layer; and
a laser debonding test structure disposed in the back-end-of-line region, the laser debonding test structure comprising a testable metal plate layer disposed within the at least one interlayer dielectric layer between the first level of metal interconnects and the second level of metal interconnects, a set of test pads, and a set of vias, at least a subset of vias in the set of vias extending from at least one test pad in the set of test pads to the testable metal plate layer disposed within the at least one interlayer dielectric layer between the first level of metal interconnects and the second level of metal interconnects.

19. The integrated circuit of claim 18, wherein the semiconductor structure further comprises a metal-insulator-metal capacitor disposed within the at least one interlayer dielectric layer separating the first level of metal interconnects and the second level of metal interconnects, the metal-insulator-metal capacitor comprising a first metal capacitor plate and a second metal capacitor plate separated by an insulating layer, wherein the testable metal plate layer of the laser debonding test structure is substantially coplanar with the first metal capacitor plate.

20. The integrated circuit of claim 18, wherein the laser debonding test structure is disposed proximate an outer edge of the semiconductor structure, and wherein the front-end-of-line region comprises one or more active device components in an inner region of the semiconductor structure spaced apart from the outer edge of the semiconductor structure.
